(19) United States
(12) Patent Application Publication
(10) Pub. No.: US 2024/0404941 A1
(43) Pub. Date: Dec. 5, 2024

(54) SEMICONDUCTOR DEVICE AND PACKAGE STRUCTURE OF SEMICONDUCTOR DEVICE

(71) Applicant: ROHM CO., LTD., Kyoto-shi (JP)

(72) Inventor: Asuma IMAMURA, Kyoto-shi (JP)

(21) Appl. No.: 18/796,813

(22) Filed: Aug. 7, 2024

Related U.S. Application Data
(63) Continuation of application No. PCT/JP2023/002555, filed on Jan. 27, 2023.

(30) Foreign Application Priority Data
Feb. 15, 2022 (JP) 2022-021567

(51) Int. Cl. H01L 23/498; H01L 23/00; H01L 23/31

(52) U.S. Cl. CPC H01L 23/49844; H01L 23/3121; H01L 24/29; H01L 24/30; H01L 24/32; H01L 24/37; H01L 24/40; H01L 24/48; H01L 24/73; H01L 2224/29139; H01L 2224/29147; H01L 2224/29187; H01L 2224/29639; H01L 2224/30505; H01L 2224/32225; H01L 2224/37147; H01L 2224/40225; H01L 2224/48225; H01L 2224/48465; H01L 2224/48472; H01L 2224/73263; H01L 2224/73265; H01L 2924/13091

(57) ABSTRACT

A semiconductor device includes a semiconductor element including first, second and third electrodes, where energization of the first and third electrodes is controlled by voltage application to the second electrode. The semiconductor device further includes a first lead connected to the first electrode, a second lead connected to the second electrode, a third lead connected to the third electrode, a fourth lead, and a sealing resin covering at least the semiconductor element. The third lead is exposed from the sealing resin to a second side in a thickness direction. The fourth lead is bonded to the semiconductor element and exposed from the sealing resin to the second side in the thickness direction. The semiconductor element includes a switching function unit. The impedance of a path from the switching function unit to the fourth lead is larger than that of a path from the switching function unit to the third lead.

### TECHNICAL FIELD

The present disclosure relates to a semiconductor device and a package structure of the semiconductor device.

### BACKGROUND ART

Conventionally, semiconductor devices each provided with a semiconductor element having a switching function are used in various electric circuits. JP-A-2020-038914 discloses an example of a conventional semiconductor device. The semiconductor device disclosed in JP-A-2020-038914 includes a semiconductor element, a plurality of leads, and a sealing resin. A drain electrode of the semiconductor element is electrically bonded to an obverse surface of one of the leads. A reverse surface of the lead is exposed from the sealing resin. The reverse surface is bonded to circuit wiring with solder.

### BRIEF DESCRIPTION OF THE DRAWINGS

FIG. 1 is a plan view showing a semiconductor device according to a first embodiment of the present disclosure.

FIG. 2 is a bottom view showing the semiconductor device according to the first embodiment of the present disclosure.

FIG. 3 is a plan view showing a main part of the semiconductor device according to the first embodiment of the present disclosure.

FIG. 4 is a cross-sectional view along line IV-IV in FIG. 3.

FIG. 5 is a cross-sectional view along line V-V in FIG. 3.

FIG. 6 is a cross-sectional view along line VI-VI in FIG. 3.

FIG. 7 is a cross-sectional view along line VII-VII in FIG. 3.

FIG. 8 is a circuit diagram showing the semiconductor device according to the first embodiment of the present disclosure.

FIG. 9 is a plan view showing a main part of a package structure of the semiconductor device according to the first embodiment of the present disclosure.

FIG. 10 is a cross-sectional view showing a first variation of the semiconductor device according to the first embodiment of the present disclosure.

FIG. 11 is an enlarged cross-sectional plan view showing a main part of the first variation of the semiconductor device according to the first embodiment of the present disclosure.

FIG. 12 is a plan view showing a main part of a second variation of the semiconductor device according to the first embodiment of the present disclosure.

FIG. 13 is a cross-sectional view showing a semiconductor device according to a second embodiment of the present disclosure.

FIG. 14 is a circuit diagram showing the semiconductor device according to the second embodiment of the present disclosure.

FIG. 15 is a circuit diagram showing the semiconductor device according to a third embodiment of the present disclosure.

FIG. 16 is a plan view showing a main part of a package structure of a semiconductor device according to a fourth embodiment of the present disclosure.

FIG. 17 is a cross-sectional view along line XVII-XVII in FIG. 16.

FIG. 18 is a circuit diagram showing a package structure of the semiconductor device according to the fourth embodiment of the present disclosure.

FIG. 19 is a plan view showing a semiconductor device according to a fifth embodiment of the present disclosure.

FIG. 20 is a plan view showing a main part of a package structure of the semiconductor device according to the fifth embodiment of the present disclosure.

FIG. 21 is a cross-sectional view along line XXI-XXI in FIG. 19.

FIG. 22 is a cross-sectional view along line XXII-XXII in FIG. 19.

FIG. 23 is a plan view showing a semiconductor device according to a sixth embodiment of the present disclosure.

FIG. 24 is a cross-sectional view along line XXIV-XXIV in FIG. 23.

FIG. 25 is a cross-sectional view along line XXV-XXV in FIG. 23.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”. Further, the phrase “a plane A faces (a first side or a second side) in a direction B” is not limited to the case where the angle of the plane A with respect to the direction B is 90°, but also includes the case where the plane A is inclined to the direction B.

### First Embodiment

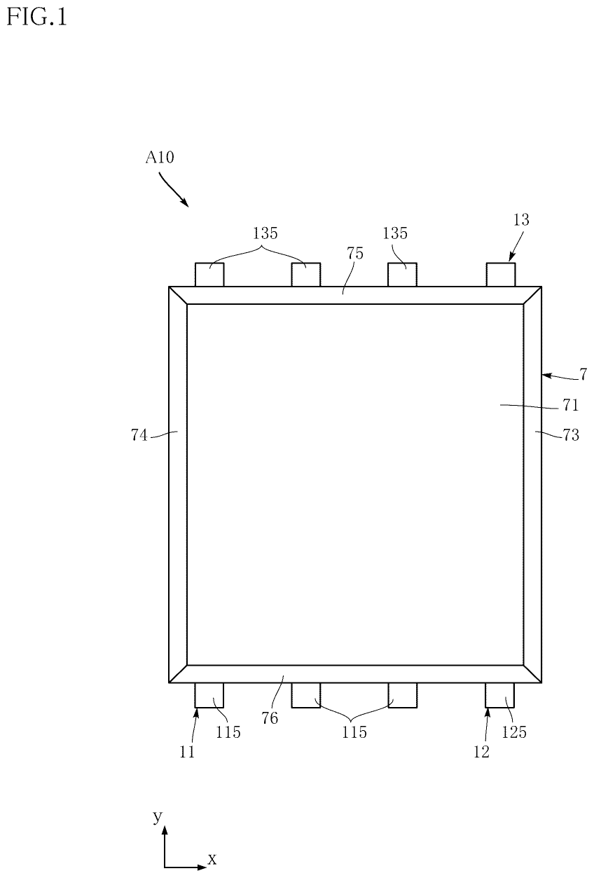

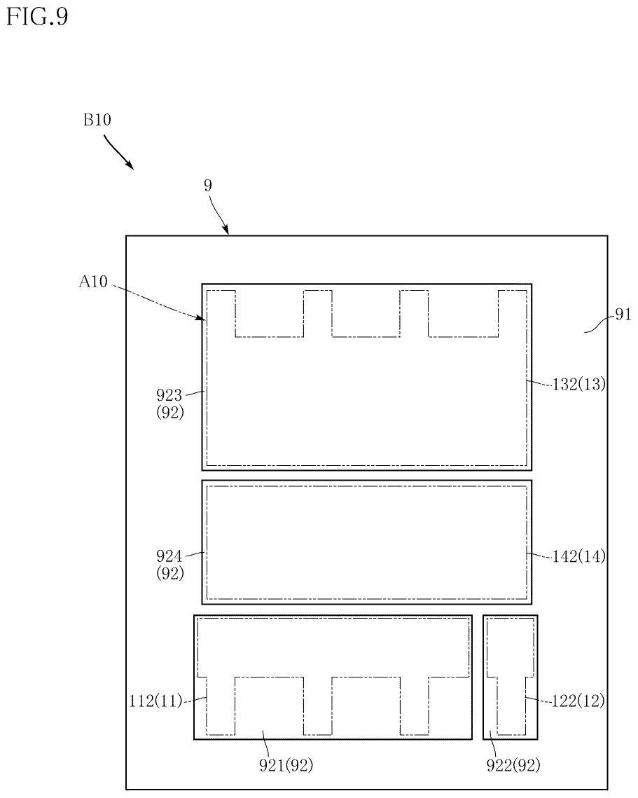

FIGS. 1 to 8 show a semiconductor device according to a first embodiment of the present disclosure. A semiconductor device A10 of the present embodiment has a first lead 11, a second lead 12, a third lead 13, a fourth lead 14, a semiconductor element 2, a first bonding portion 61, a second bonding portion 62, a plurality of wires 65, a wire 66, and a sealing resin 7. FIG. 9 is a package structure of a semiconductor device according to the first embodiment of the present disclosure. A package structure B10 of a semiconductor device according to the present embodiment includes the semiconductor device A10 and a substrate 9.

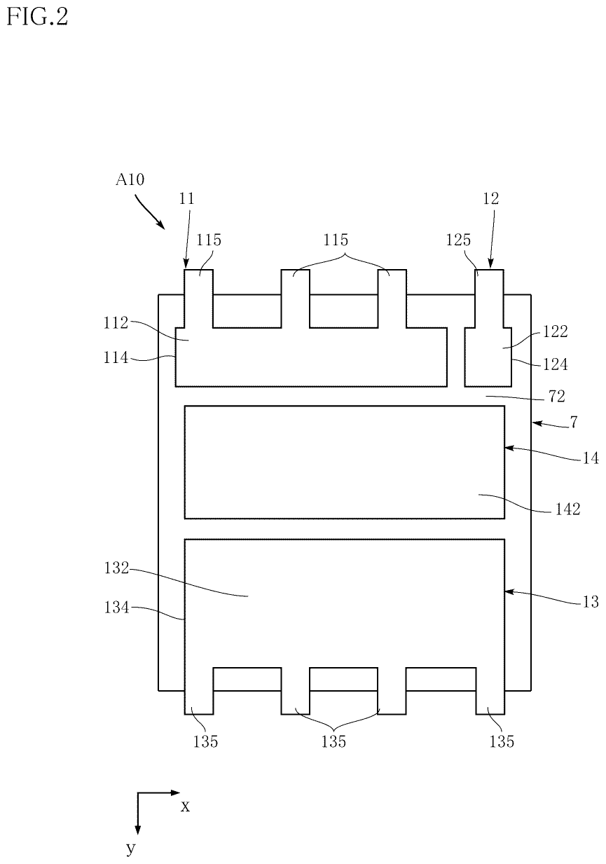

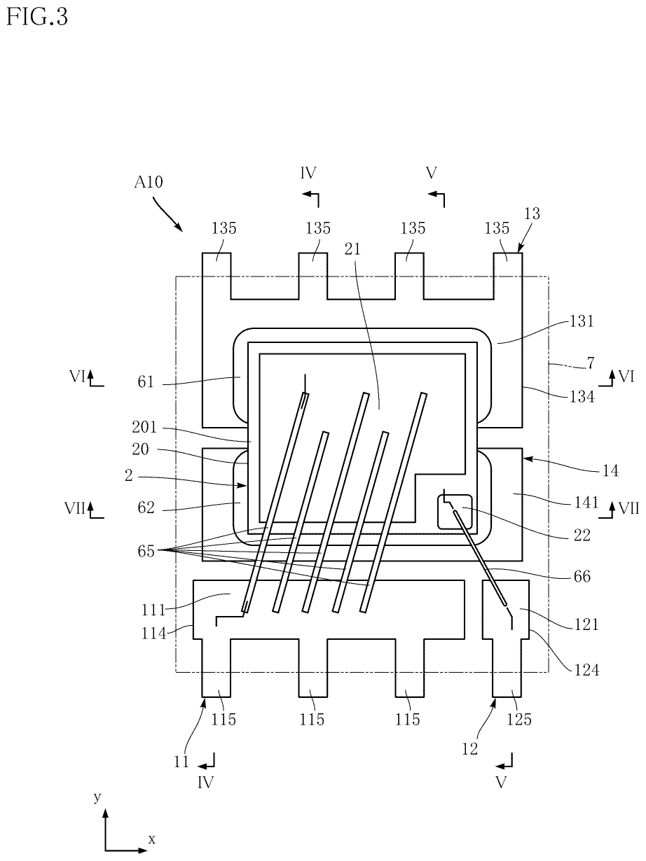

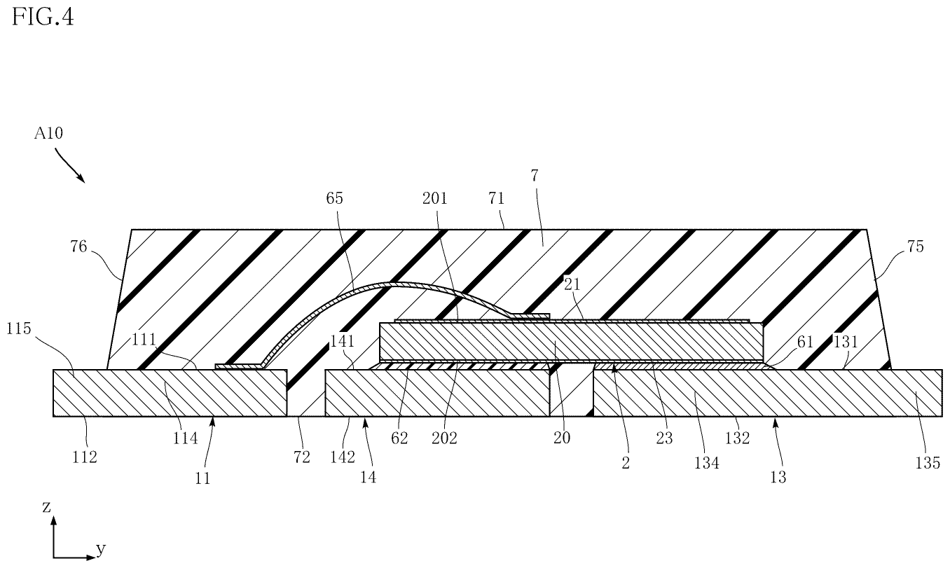

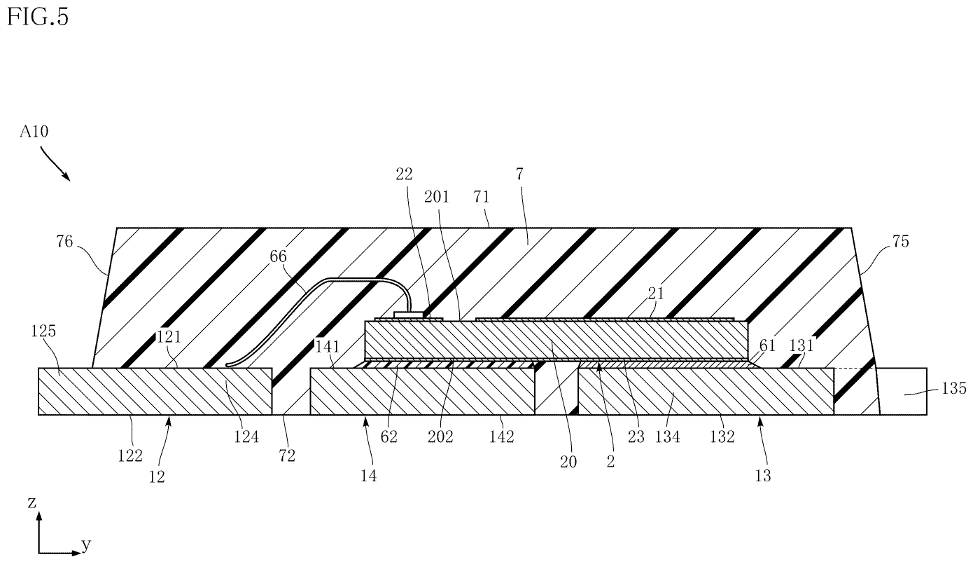

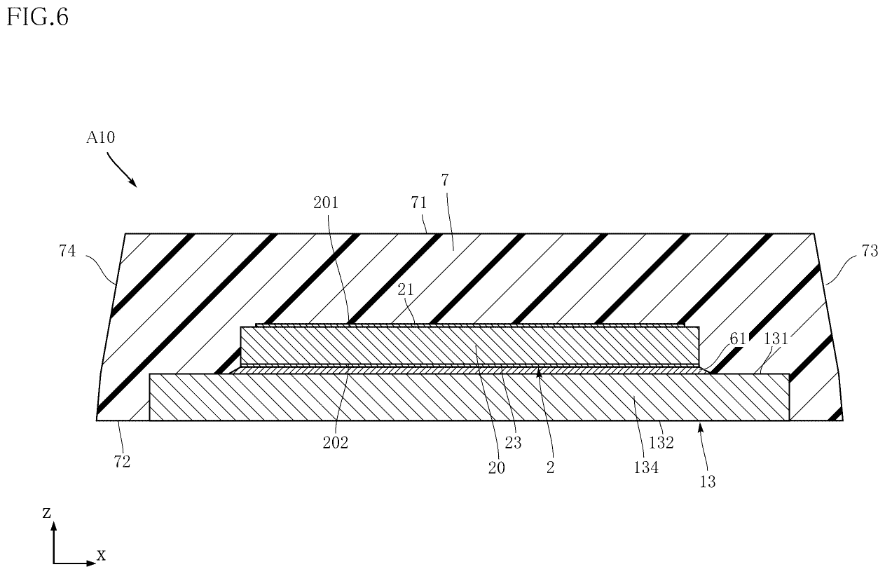

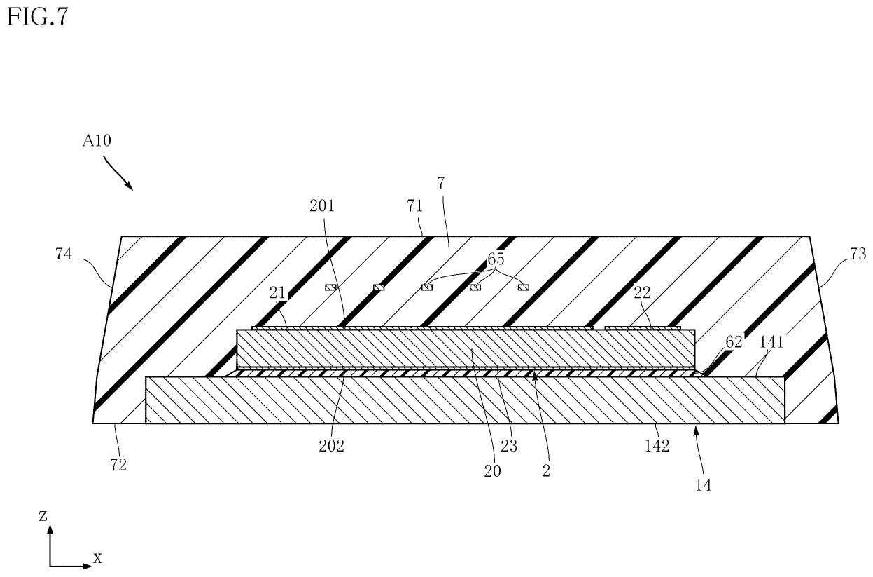

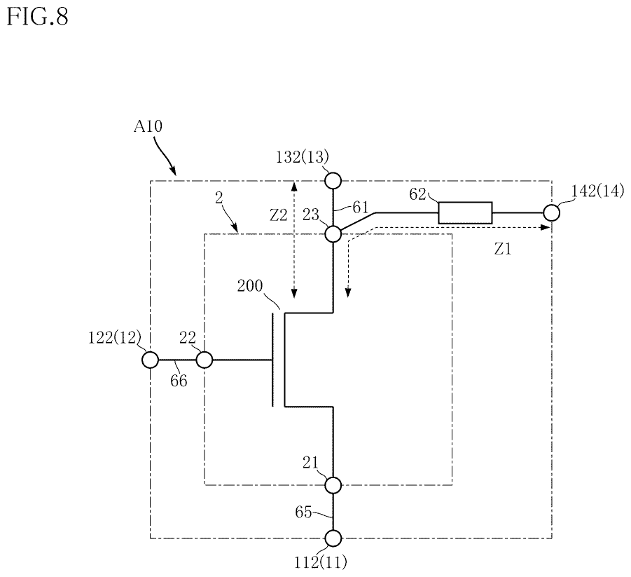

FIG. 1 is a plan view showing the semiconductor device A10. FIG. 2 is a bottom view showing the semiconductor device A10. FIG. 3 is a plan view showing a main part of the semiconductor device A10. FIG. 4 is a cross-sectional view along line IV-IV in FIG. 3. FIG. 5 is a cross-sectional view along line V-V in FIG. 3. FIG. 6 is a cross-sectional view along line VI-VI in FIG. 3. FIG. 7 is a cross-sectional view along line VII-VII in FIG. 3. FIG. 8 is a circuit diagram showing the semiconductor device A10. FIG. 9 is a plan view showing a main part of the package structure B10 of a semiconductor device. In these figures, the z direction is an example of a “thickness direction”, and the y direction is an example of a “first direction”.

As shown in FIGS. 1 and 2, the semiconductor device A10 has a rectangular shape (or substantially a rectangular shape) as viewed in the z direction. The size of the semiconductor device A10 is not particularly limited. In the present embodiment, the semiconductor device A10 may have a dimension of 2.6 mm to 3.6 mm in the x direction, a dimension of 2.6 mm to 3.6 mm in the y direction, and a dimension of 0.5 mm to 1.5 mm in the z direction.

### First Lead 11, Second Lead 12, Third Lead 13, Fourth Lead 14:

The first lead 11, the second lead 12, the third lead 13, and the fourth lead 14 are formed by punching and bending a metal plate, for example. The first lead 11, the second lead 12, the third lead 13, and the fourth lead 14 may be made of either one of copper (Cu) and nickel (Ni), or an alloy of Cu or Ni. The first lead 11, the second lead 12, the third lead 13, and the fourth lead 14 may be provided with plating layers at appropriate portions so as to improve solder wettability or wire bonding strength, for example. Each of the first lead 11, the second lead 12, the third lead 13, and the fourth lead 14 may have a thickness of 0.1 mm to 0.3 mm.

The arrangement of the first lead 11, the second lead 12, the third lead 13, and the fourth lead 14 is not particularly limited. In the present embodiment, the third lead 13 is spaced apart from the first lead 11 and the second lead 12 in the y direction, as shown in FIG. 3. The fourth lead 14 is located between the first and second leads 11 and 12 and the third lead 13 in the y direction. The first lead 11 and the second lead 12 are aligned in the x direction. The first lead 11, the second lead 12, the third lead 13, and the fourth lead 14 are spaced apart from each other as viewed in the z direction. As viewed in the z direction, the third lead 13 and the fourth lead 14 are larger in size than the first lead 11 and the second lead 12. As viewed in the z direction, the second lead 12 has the smallest size.

As shown in FIGS. 3 and 4, the first lead 11 has a first bonding portion 114 and a plurality of (three in the present embodiment) first extending portions 115. The first bonding portion 114 is located on a first side (upper side in FIG. 4) in the z direction with respect to the first extending portions 115. The first bonding portion 114 is located inward in the y direction with respect to the first extending portions 115. The first extending portions 115 extend from the first bonding portion 114 to a second side in the y direction. As viewed in the z direction, the tip of each first extending portion 115 protrudes from the sealing resin 7 to the second side in the y direction. The first lead 11 has a first obverse surface 111 and a first mounting surface 112. The first obverse surface 111 faces the first side in the z direction. The first mounting surface 112 faces a second side in the z direction. The first mounting surface 112 is bonded with a bonding material such as solder when the semiconductor device A10 is mounted onto the substrate 9. In the illustrated example, the first lead 11 has a flat shape along the x direction and the y direction. However, the first lead 11 is not limited to a specific shape, and may have a bent portion, for example.

As shown in FIGS. 3 and 5, the second lead 12 has a second bonding portion 124 and a second extending portion 125. The second bonding portion 124 is located on the first side (upper side in FIG. 5) in the z direction with respect to the second extending portion 125. The second bonding portion 124 is located inward in the y direction with respect to the second extending portion 125. The second extending portion 125 extends from the second bonding portion 124 to the second side in the y direction. As viewed in the z direction, the tip of the second extending portion 125 protrudes from the sealing resin 7 to the second side in the y direction. The second lead 12 has a second obverse surface 121 and a second mounting surface 122. The second obverse surface 121 faces the first side in the z direction. The second mounting surface 122 faces a second side in the z direction. The second mounting surface 122 is bonded with a bonding material such as solder when the semiconductor device A10 is mounted onto the substrate 9. In the illustrated example, the second lead 12 has a flat shape along the x direction and the y direction. However, the second lead 12 is not limited to a specific shape, and may have a bent portion, for example.

As shown in FIGS. 3 to 6, the third lead 13 has a third bonding portion 134 and a plurality of (four in the present embodiment) third extending portions 135. The third bonding portion 134 has a rectangular shape as viewed in the z direction, for example. The third extending portions 135 extend from the third bonding portion 134 to a first side in the y direction. As viewed in the z direction, the tip of each third extending portion 135 protrudes from the sealing resin 7 to the first side in the y direction. The third lead 13 has a third obverse surface 131 and a third mounting surface 132. The third obverse surface 131 faces the first side in the z direction. The third mounting surface 132 faces the second side in the z direction. The third mounting surface 132 is bonded with a bonding material such as solder when the semiconductor device A10 is mounted onto the substrate 9. In the illustrated example, the third lead 13 has a flat shape along the x direction and the y direction. However, the third lead 13 is not limited to a specific shape, and may have a bent portion, for example.

As shown in FIGS. 3 to 5 and 7, the fourth lead 14 has a rectangular shape as viewed in the z direction, for example. The fourth lead 14 has a fourth obverse surface 141 and a fourth mounting surface 142. The fourth obverse surface 141 faces the first side in the z direction. The fourth mounting surface 142 faces the second side in the z direction. The fourth mounting surface 142 is bonded with a bonding material when the semiconductor device A10 is mounted onto the substrate 9. In the illustrated example, the fourth lead 14 has a flat shape along the x direction and the y direction. However, the fourth lead 14 is not limited to a specific shape, and may have a bent portion, for example.

In the present embodiment, the first mounting surface 112, the second mounting surface 122, the third mounting surface 132, and the fourth mounting surface 142 each have a shape along the xy plane, and are flush with each other. Note that “the first mounting surface 112, the second mounting surface 122, the third mounting surface 132, and the fourth mounting surface 142 are flush with each other” not only refers to the case where the positions thereof in the z direction strictly coincide with each other, but also to the case where the positions thereof in the z direction are deviated due to unavoidable errors in metal processing, for example.

### Semiconductor Element 2:

The semiconductor element 2 is an element that exerts an electrical function of the semiconductor device A10 and has a switching function. The type of the semiconductor element 2 is not particularly limited. In the present embodiment, the semiconductor element 2 is configured as a transistor (MOSFET). As shown in FIGS. 3 to 6, the semiconductor element 2 has an element body 20, a first electrode 21, a second electrode 22, and a third electrode 23.

The element body 20 has a rectangular shape as viewed in the z direction. The element body 20 has an element obverse surface 201 and an element reverse surface 202. The element obverse surface 201 and the element reverse surface 202 face away from each other in the z direction. The element obverse surface 201 faces the first side in the z direction. The element reverse surface 202 faces the second side in the z direction.

The element body 20 has a switching function unit 200 built therein. The switching function unit 200 includes a semiconductor structure for realizing the switching function of the semiconductor element 2. In other words, the switching function unit 200 includes an n-type semiconductor and a p-type semiconductor that are adjacent to each other to form a channel having, for example, a combination of an n-p junction and a p-n junction.

The first electrode 21 and the second electrode 22 are arranged on the element obverse surface 201. The third electrode 23 is arranged on the element reverse surface 202. The constituent material of the first electrode 21, the second electrode 22, and the third electrode 23 is not particularly limited, and may be either one of copper (Cu) and aluminum (Al), or an alloy of Cu or Al. In the present embodiment, the first electrode 21 is a source electrode, the second electrode 22 is a gate electrode, and the third electrode 23 is a drain electrode.

In the present embodiment, the first electrode 21 covers most of the element obverse surface 201. The second electrode 22 is arranged at a corner (lower right corner in FIG. 3) of the element obverse surface 201. The third electrode 23 covers the entirety (or substantially the entirety) of the element reverse surface 202.

### First Bonding Portion 61:

As shown in FIGS. 3 to 6, the first bonding portion 61 bonds the third electrode 23 of the semiconductor element 2 to the third obverse surface 131 of the third lead 13. In the present embodiment, a portion of the third electrode 23 on the first side in the y direction is bonded to the third obverse surface 131 of the third lead 13 with the first bonding portion 61. The first bonding portion 61 comprises a conductive bonding material such as solder, silver (Ag) paste, or a silver (Ag) sintered material. The first bonding portion 61 is preferably a good conductor, and more preferably has high thermal conductivity.

### Second Bonding Portion 62:

As shown in FIGS. 3 to 5 and 7, the second bonding portion 62 bonds the third electrode 23 of the semiconductor element 2 to the fourth obverse surface 141 of the fourth lead 14. In the present embodiment, a portion of the third electrode 23 on the second side in the y direction is bonded to the fourth obverse surface 141 of the fourth lead 14 with the second bonding portion 62. The second bonding portion 62 contains a material having an impedance higher than a good conductor such as silver (Ag) or copper (Cu). It is preferable that the second bonding portion 62 contain a material having thermal conductivity higher than a resin constituting the sealing resin 7, for example. Such a material may be an insulating, high thermal-conductivity paste containing silicone or grease, for example. In other words, the concept of having high impedance in the present disclosure includes being substantially insulating. Other examples of the material of the second bonding portion 62 include an insulating, high thermal-conductivity sheet containing silicone. Using an insulating, high thermal-conductivity sheet as the second bonding portion 62 is advantageous in further uniformizing the thickness of the second bonding portion 62.

### Wires 65:

As shown in FIGS. 3 and 4, the wires 65 are connected to the first electrode 21 of the semiconductor element 2 and the first obverse surface 111 of the first lead 11 to electrically connect the first electrode 21 and the first lead 11 to each other. Each wire 65 is not particularly limited to a specific configuration, and may be a linear or band-like conductive member containing gold (Au), aluminum (Al), or copper (Cu). In the illustrated example, the wires 65 are made of aluminum (Al) and has a band shape.

### Wire 66:

As shown in FIGS. 3 and 5, the wire 66 is connected to the second electrode 22 of the semiconductor element 2 and the second obverse surface 121 of the second lead 12 to electrically connect the second electrode 22 and the second lead 12 to each other. The wire 66 is not particularly limited to a specific configuration, and may be a linear or band-like conductive member containing gold (Au), aluminum (Al), or copper (Cu). In the illustrated example, the wire 66 is made of gold (Au) and has a linear shape.

### Sealing Resin 7:

The sealing resin 7 covers a portion of each of the first lead 11, the second lead 12, the third lead 13, and the fourth lead 14, and also covers the semiconductor element 2, the first bonding portion 61, the second bonding portion 62, the wires 65, and the wire 66. The sealing resin 7 is made of a black epoxy resin, for example.

As shown in FIGS. 1 to 7, the sealing resin 7 has a sealing resin obverse surface 71, a sealing resin reverse surface 72, and sealing resin side surfaces 73, 74, 75, and 76. The sealing resin obverse surface 71 and the sealing resin reverse surface 72 face away from each other in the z direction. The sealing resin obverse surface 71 faces the first side in the z direction. The sealing resin reverse surface 72 faces the second side in the z direction. The sealing resin side surface 73 is connected to the sealing resin obverse surface 71 and the sealing resin reverse surface 72, and faces a first side in the x direction. The sealing resin side surface 74 is connected to the sealing resin obverse surface 71 and the sealing resin reverse surface 72, and faces a second side in the x direction. The sealing resin side surface 75 is connected to the sealing resin obverse surface 71 and the sealing resin reverse surface 72, and faces the first side in the y direction. The sealing resin side surface 76 is connected to the sealing resin obverse surface 71 and the sealing resin reverse surface 72, and faces the second side in the y direction.

The third extending portions 135 protrude from the sealing resin side surface 75 to the first side in the y direction. The first extending portions 115 and the second extending portion 125 protrude from the sealing resin side surface 76 to the second side in the y direction. The first mounting surface 112, the second mounting surface 122, the third mounting surface 132, and the fourth mounting surface 142 are exposed from the sealing resin reverse surface 72. In the present embodiment, the sealing resin reverse surface 72 is flush with the first mounting surface 112, the second mounting surface 122, the third mounting surface 132, and the fourth mounting surface 142.

In the circuit diagram of FIG. 8 showing the semiconductor device A10, the third electrode 23 is connected to the third mounting surface 132 (the third lead 13) via the first bonding portion 61, and to the fourth mounting surface 142 (the fourth lead 14) via the second bonding portion 62. The path from the switching function unit 200 to the fourth mounting surface 142 (the fourth lead 14) includes the third electrode 23 and the second bonding portion 62, and the impedance of the path is defined as an impedance Z1. On the other hand, the path from the switching function unit 200 to the third mounting surface 132 (the third lead 13) includes the third electrode 23 and the first bonding portion 61, and the impedance of the path is defined as an impedance Z2. Since the second bonding portion 62 has the configuration described above, the impedance Z1 is larger than the impedance Z2. In particular, the first bonding portion 61 contains a good conductor whereas the second bonding portion 62 contains an insulating, high thermal-conductivity paste, and the impedance Z1 is therefore large to the extent that it can be recognized as infinite (insulated) as compared to the impedance Z2.

FIG. 9 shows the package structure B10 of a semiconductor device, where the semiconductor device A10 is mounted on the substrate 9. The substrate 9 has an insulating portion 91 and a wiring portion 92. The insulating portion 91 is made of an insulating material such as epoxy resin or ceramic. The wiring portion 92 is made of a conductor, such as copper (Cu) or nickel (Ni), formed on a surface of the insulating portion 91 or inside the insulating portion 91. The wiring portion 92 includes a first region 921, a second region 922, a third region 923, and a fourth region 924. In the present embodiment, the first region 921, the second region 922, the third region 923, and the fourth region 924 are arranged on one surface of the insulating portion 91.

The first region 921 is electrically bonded to the first mounting surface 112 of the first lead 11 with solder or the like. The first region 921 is electrically connected to a terminal (not illustrated) that receives and outputs the main current switched by the semiconductor element 2. The second region 922 is electrically bonded to the second mounting surface 122 of the second lead 12 with solder or the like. The second region 922 is electrically connected to a terminal (not illustrated) that receives a control signal for controlling the switching function of the semiconductor element 2. The third region 923 is electrically bonded to the third mounting surface 132 of the third lead 13 with solder or the like. The third region 923 is electrically connected to another terminal (not illustrated) that receives and outputs the main current switched by the semiconductor element 2. The fourth region 924 is electrically bonded to the fourth mounting surface 142 of the fourth lead 14 with solder or the like. The fourth region 924 is electrically connected to a ground line (not illustrated).

Next, advantages of the semiconductor device A10 and the package structure B10 of a semiconductor device will be described.

As shown in FIG. 5, the third electrode 23 arranged on the element reverse surface 202 of the element body 20 is bonded to the third lead 13 and the fourth lead 14. This allows the heat generated in the semiconductor element 2 (the element body 20) during the operation of the semiconductor device A10 to be dissipated to the outside via the third lead 13 and the fourth lead 14. As shown in FIG. 8, the impedance Z1 is larger than the impedance Z2. Thus, the current flowing through the third lead 13 is prevented from flowing through the fourth lead 14 to the outside. This makes it possible to suppress the emission of electromagnetic noise from, for example, the fourth region 924 to which the fourth lead 14 is bonded. Thus, the present embodiment can promote heat dissipation and suppress noise.

When the second bonding portion 62 contains an insulating, high thermal-conductivity paste, the second bonding portion 62 has a higher thermal conductivity than, for example, the sealing resin 7. This promotes dissipation of heat from the semiconductor element 2 (the element body 20) to the fourth lead 14.

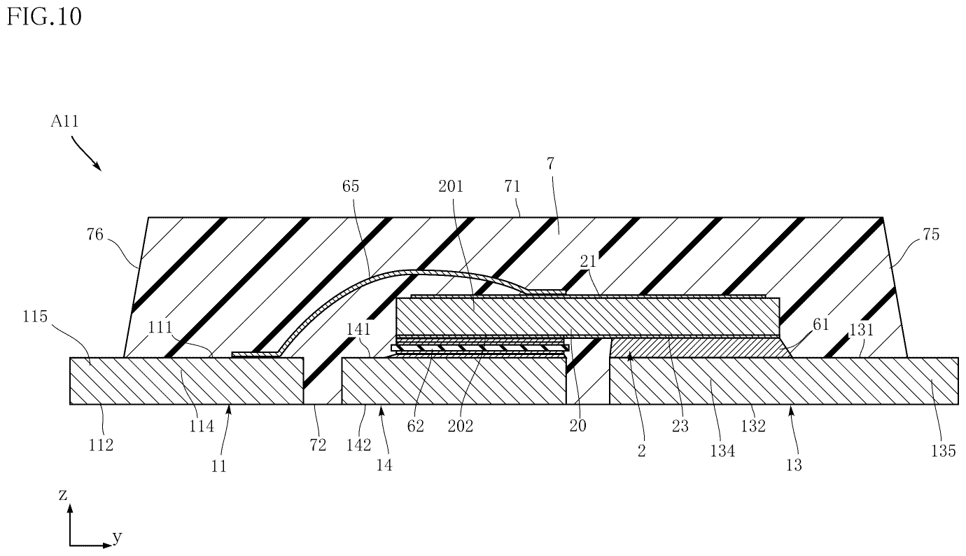

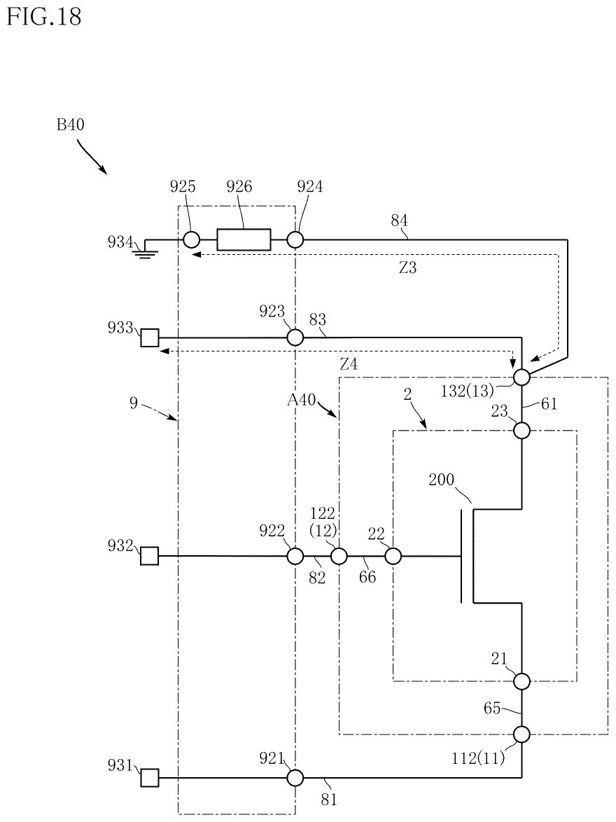

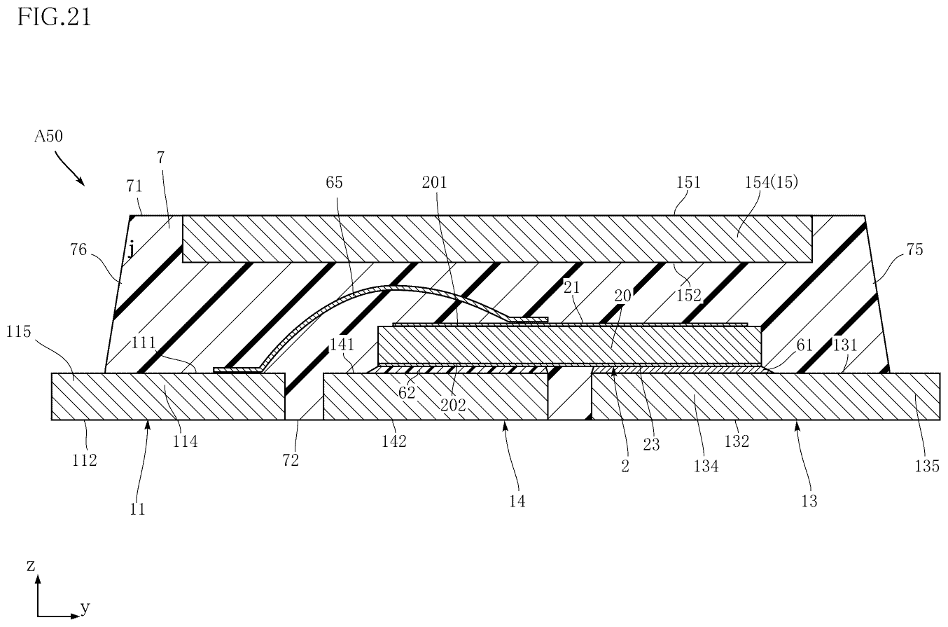

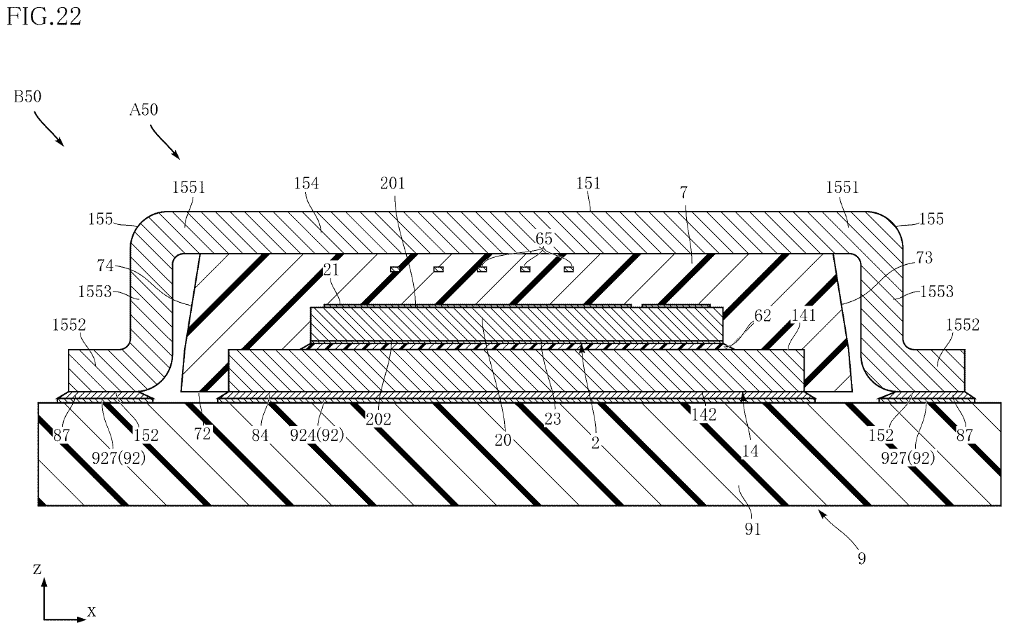

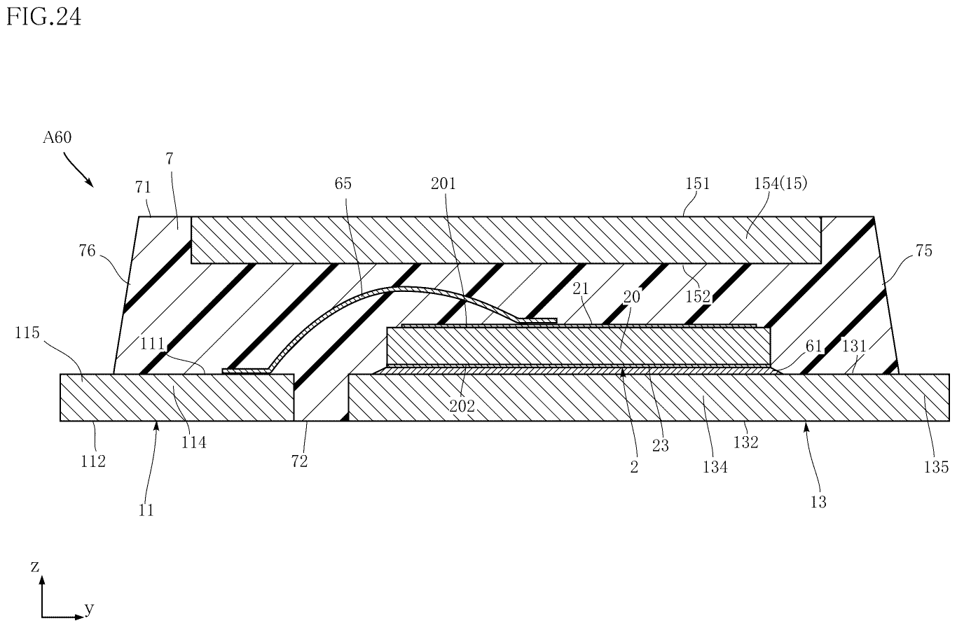

FIGS. 10 to 25 show other embodiments of the present disclosure. In these figures, elements that are the same as or similar to those in the above embodiment are provided with the same reference numerals as in the above embodiment. The configurations of the elements in each variation and each embodiment can be combined as appropriate as long as the combination does not cause technical inconsistency. The second bonding portion 62 contains an insulating, high thermal-conductivity paste, and has high insulation. This allows the impedance Z1 to be much higher than the impedance Z2. This is preferable for promoting heat dissipation and suppressing noise.

In the package structure B10 of a semiconductor device, the fourth lead 14 is electrically bonded to the fourth region 924. The fourth region 924 is grounded to the ground line (not illustrated). This allows the fourth lead 14 to be more electrically stable.

The fourth lead 14 is larger in size than each of the first lead 11 and the second lead 12. This is advantageous for promoting heat dissipation.

### First Variation of the First Embodiment

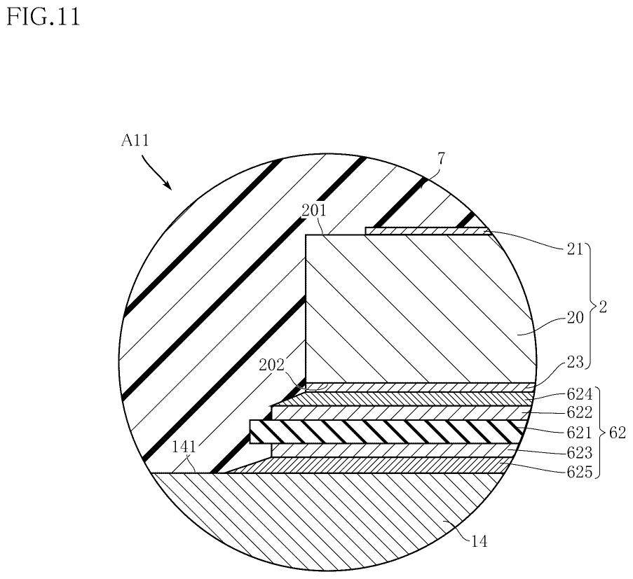

FIGS. 10 and 11 show a first variation of the semiconductor device A10. A semiconductor device A11 of the present variation is different from the example described above in the configuration of the second bonding portion 62.

The second bonding portion 62 of the present example includes an insulating layer 621, a metal layer 622, and a metal layer 623. The insulating layer 621 is a plate-like member made of ceramic such as alumina (Al₂O₃), aluminum nitride (AlN), or silicon nitride (SiN). The metal layer 622 is formed on one surface (the surface facing the first side in the z direction) of the insulating layer 621, and contains copper (Cu), for example. The metal layer 623 is formed on one surface (the surface facing the second side in the z direction) of the insulating layer 621, and contains copper (Cu), for example. The insulating layer 621, the metal layer 622, and the metal layer 623 as described above constitute a direct bonded copper (DBC) substrate, for example.

The second bonding portion 62 of the present example further includes a conductive bonding member 624 and a conductive bonding member 625. The conductive bonding member 624 bonds the third electrode 23 of the semiconductor element 2 to the metal layer 622. The conductive bonding member 625 bonds the fourth obverse surface 141 of the fourth lead 14 to the metal layer 623. Each of the conductive bonding member 624 and the conductive bonding member 625 is solder, silver (Ag) paste, or silver (Ag) sintered material, for example. The second bonding portion 62 includes the insulating layer 621, thereby insulating the third electrode 23 of the semiconductor element 2 and the fourth obverse surface 141 of the fourth lead 14 from each other while bonding them.

The present variation can also promote heat dissipation and suppress noise. As can be understood from the present variation, the specific configuration of the second bonding portion 62 is not particularly limited. The second bonding portion 62 with a DBC substrate has an advantage of being resistant to possible damage caused by the load of a heat cycle.

### Second Variation of the First Embodiment

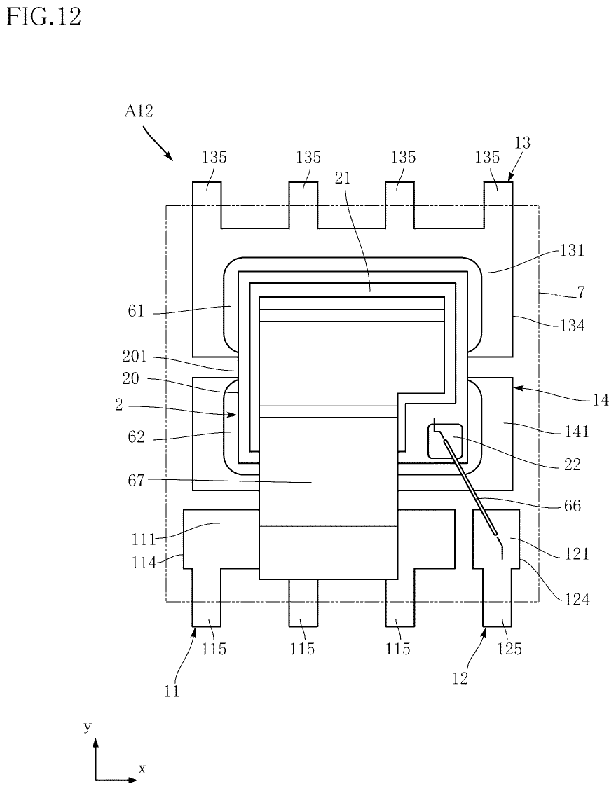

FIG. 12 shows a second variation of the semiconductor device A10. A semiconductor device A12 of the present example includes a conductive member 67 instead of the wires 65 in the above example.

The conductive member 67 is formed by cutting and bending a plate-like member made of metal such as copper (Cu). The conductive member 67 is bent as viewed in the x direction, for example. The conductive member 67 is electrically bonded to the first electrode 21 of the semiconductor element 2 and the first obverse surface 111 of the first lead 11. The electrical bonding may be performed with solder, silver (Ag) paste, or silver (Ag) sintered material, for example.

The present variation can also promote heat dissipation and suppress noise. As can be understood from the present variation, the specific configuration for electrically connecting the first electrode 21 and the first lead 11 is not particularly limited.

### Second Embodiment

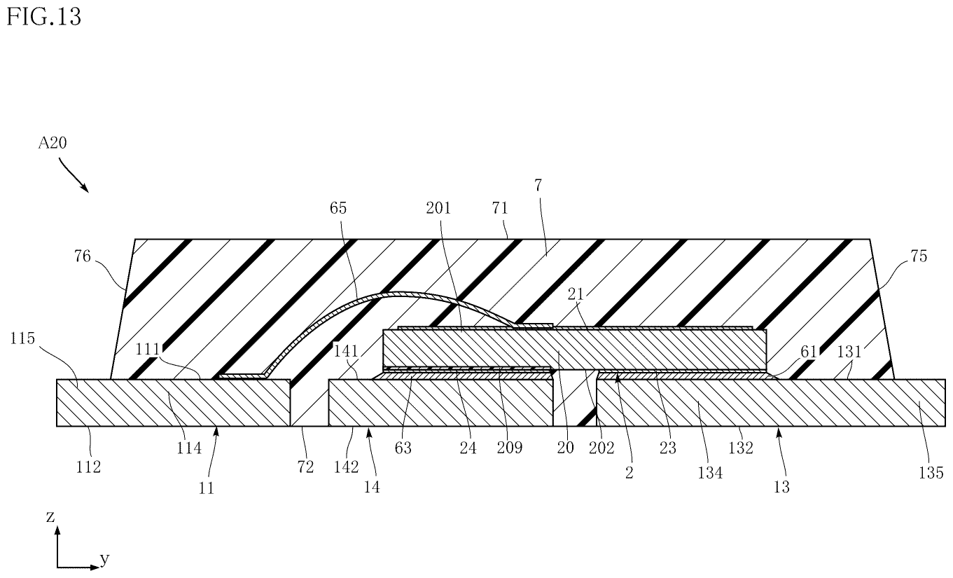

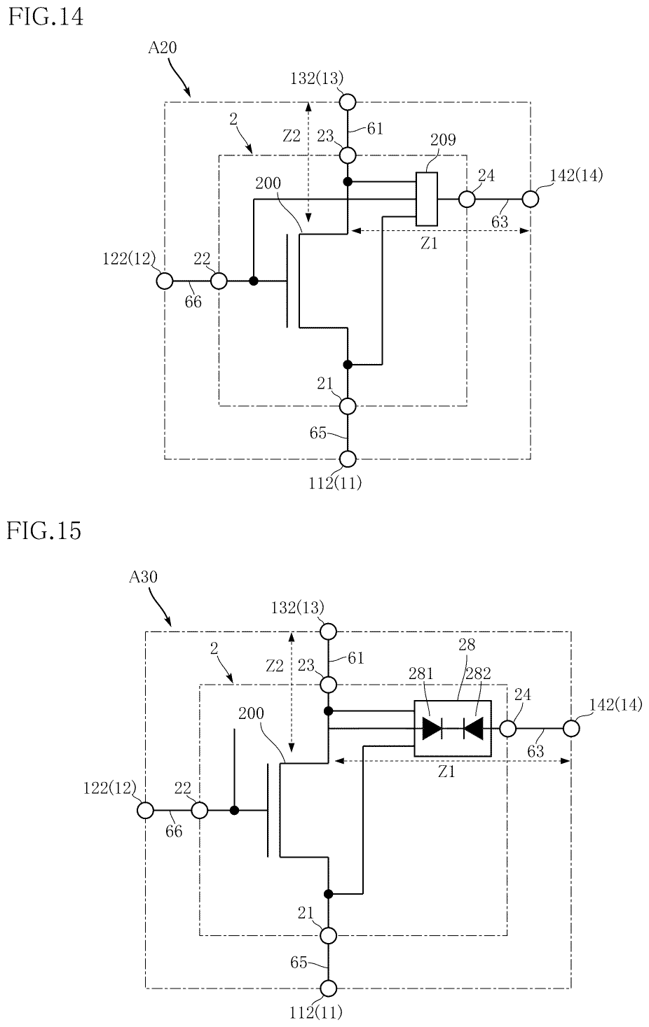

FIGS. 13 and 14 show a semiconductor device according to a second embodiment of the present disclosure. A semiconductor device A20 of the present embodiment is different from the above embodiment in the configuration of the semiconductor element 2 and the bonding configuration between the semiconductor element 2 and the fourth lead 14.

The semiconductor element 2 of the present embodiment has an element insulating layer 209 and a fourth electrode 24. The element insulating layer 209 is provided on a portion of the element reverse surface 202 of the element body 20. The element insulating layer 209 is arranged so as to avoid the third electrode 23 as viewed in the z direction. In the illustrated example, the element insulating layer 209 is located on the second side in the y direction with respect to the third electrode 23.

The fourth electrode 24 is formed on the element insulating layer 209. In other words, the element insulating layer 209 is provided between the element body 20 and the fourth electrode 24. The element insulating layer 209 contains an insulating material such as silicon dioxide (SiO₂) or silicon nitride (SiN). The element insulating layer 209 insulates the fourth electrode 24 from the switching function unit 200 (the element body 20). The fourth electrode 24 is also insulated from the first electrode 21, the second electrode 22, and the third electrode 23.

The fourth electrode 24 is bonded to the fourth obverse surface 141 of the fourth lead 14 with a third bonding portion 63. The third bonding portion 63 is made of solder, silver (Ag) paste, or a silver (Ag) sintered material, for example.

As shown in FIG. 14, the path from the switching function unit 200 to the fourth mounting surface 142 (the fourth lead 14) includes the element insulating layer 209. Thus, the impedance Z1 is larger than the impedance Z2. In particular, the first bonding portion 61 contains a good conductor whereas the element insulating layer 209 contains an insulating material, and the impedance Z1 is therefore large to the extent that it can be recognized as infinite (insulated) as compared to the impedance Z2.

The present embodiment can also promote heat dissipation and suppress noise. The element insulating layer 209 is very thin but has a good insulation property. This makes it possible to efficiently conduct heat from the element body 20 to the fourth lead 14, and thus is preferable for promoting heat dissipation. This is also an advantage for increasing the impedance Z1.

### Third Embodiment

FIG. 15 shows a semiconductor device according to a third embodiment of the present disclosure. A semiconductor device A30 of the present embodiment is different from the embodiments described above in the configuration of the semiconductor element 2, but is similar to, for example, the semiconductor device A20, in the other configurations.

The semiconductor element 2 of the present embodiment has an insulating element portion 28. The insulating element portion 28 has a function of insulating the fourth electrode 24 and the switching function unit 200 from each other. In the illustrated example, the insulating element portion 28 includes diodes 281 and 282. The diodes 281 and 282 are connected in series and have opposite polarities. As such, the diodes 281 and 282 perform an insulating function of preventing electrical connection. The insulating element portion 28 is not particularly limited to a specific configuration, and may be built in a portion of the element body 20.

The present embodiment can also promote heat dissipation and suppress noise. Further, since the present embodiment does not need to include configurations such as the element insulating layer 209 or the DBC substrate, it is possible to further promote heat dissipation.

### Fourth Embodiment

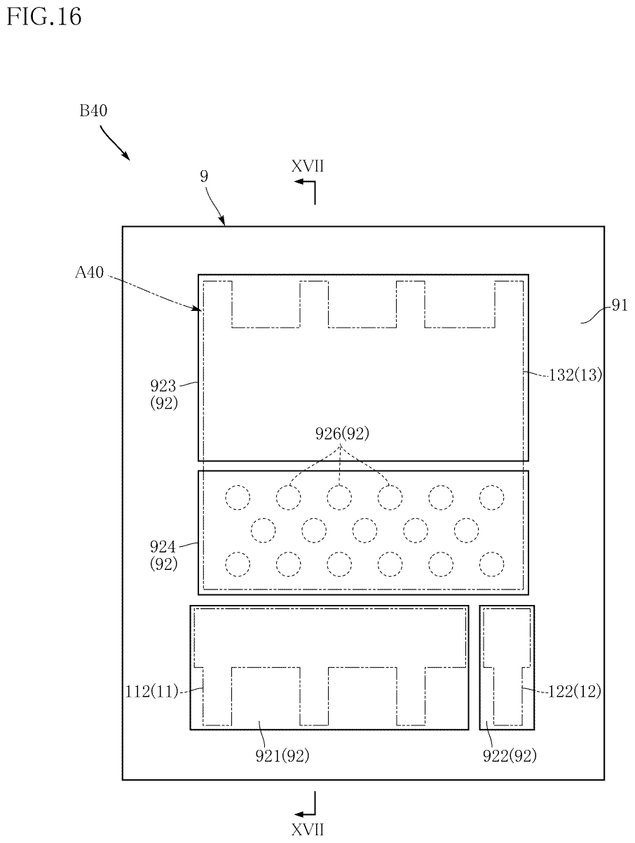

FIGS. 16 to 18 each show a package structure of a semiconductor device according to a fourth embodiment of the present disclosure. A package structure B40 of a semiconductor device according to the present embodiment includes a semiconductor device A40 and the substrate 9.

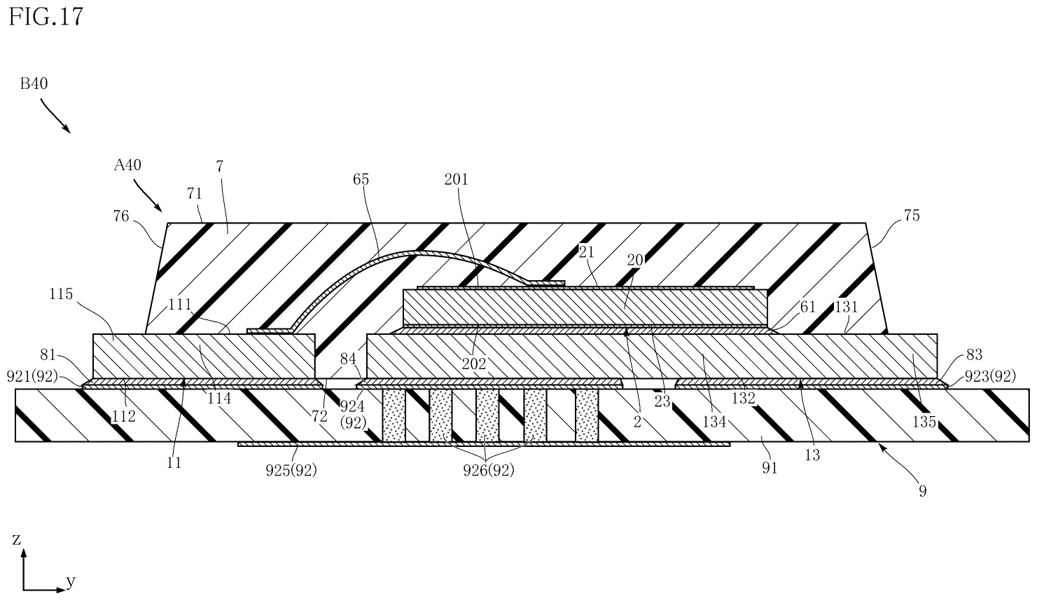

As shown in FIG. 17, the semiconductor device A40 includes the first lead 11, the second lead 12, and the third lead 13, but does not include the fourth lead 14 described above. The semiconductor element 2 includes the element body 20 (including the switching function unit 200), the first electrode 21, the second electrode 22, and the third electrode 23, but does not include the element insulating layer 209 or the insulating element portion 28 described above. The entirety of the third electrode 23 is electrically bonded to the third obverse surface 131 of the third lead 13 with the first bonding portion 61.

As shown in FIGS. 16 to 18, the wiring portion 92 of the substrate 9 according to the present embodiment includes the first region 921, the second region 922, the third region 923, the fourth region 924, a fifth region 925, a sixth region 926, a first terminal 931, a second terminal 932, a third terminal 933, and a ground terminal 934. The first mounting surface 112 of the first lead 11 is bonded to the first region 921 via a conductive bonding member 81 such as solder. The second mounting surface 122 of the second lead 12 is bonded to the second region 922 via a conductive bonding member 82 such as solder. A portion of the third mounting surface 132 of the third lead 13 is bonded to the third region 923 via a conductive bonding member 83 such as solder. Another portion of the third mounting surface 132 of the third lead 13 is bonded to the fourth region 924 via a conductive bonding member 84 such as solder.

The first region 921, the second region 922, the third region 923, and the fourth region 924 are arranged as shown in FIG. 16, and have configurations similar to those described with reference to FIG. 9. The fifth region 925 is made of a metal layer built in the insulating portion 91, for example. The fifth region 925 is electrically connected to the ground terminal 934. The ground terminal 934 is grounded by being connected to a ground line (not illustrated) outside the substrate 9.

The sixth region 926 is electrically interposed between the fourth region 924 and the fifth region 925. The specific configuration of the sixth region 926 is not particularly limited. In the present example, the sixth region 926 includes vias connecting the fourth region 924 to the fifth region 925 in the z direction. The sixth region 926 contains a material that has a higher impedance than, for example, copper (Cu) or nickel (Ni), that constitutes other regions of the wiring portion 92. Such a material of the sixth region 926 may be high thermal-conductivity resins including polycarbonate, polyethylene terephthalate, and polyamide, which are filled in the through-holes provided in the insulating portion 91. Alternatively, the sixth region 926 may be configured with a combination of a through-hole conductive portion including a conductor such as metal and a high thermal-conductivity sheet provided between the through-hole conductive portion and the fourth region 924 or the fifth region 925.

The first region 921 is electrically connected to the first terminal 931. The first terminal 931 receives and outputs the main current switched by the semiconductor element 2. The second region 922 is electrically connected to the second terminal 932. The second terminal 932 receives a control signal for controlling the switching function of the semiconductor element 2. The third region 923 is electrically connected to the third terminal 933. The third terminal 933 is another terminal that receives and outputs the main current switched by the semiconductor element 2.

The specific configurations of the first terminal 931, the second terminal 932, the third terminal 933, and the ground terminal 934 are not particularly limited. Each of the first terminal 931, the second terminal 932, the third terminal 933, and the ground terminal 934 may be a connector to which a connector or the like outside the substrate 9 is connected, or may be a mounting terminal. Alternatively, each of the first terminal 931, the second terminal 932, the third terminal 933, and the ground terminal 934 may be a portion of the wiring portion 92 onto which another electronic component is mounted (electrically bonded).

An impedance Z3 of the path from the third lead 13 to the fifth region 925 via the fourth region 924 and the sixth region 926 is larger than an impedance Z4 of the path from the third lead 13 to the third terminal 933 via the third region 923. This is because the sixth region 926 contains a material having a relatively high impedance as described above.

The present embodiment can also promote heat dissipation and suppress noise. Further, the present embodiment allows the employment of a semiconductor device having a general configuration such as the semiconductor device A40.

### Fifth Embodiment

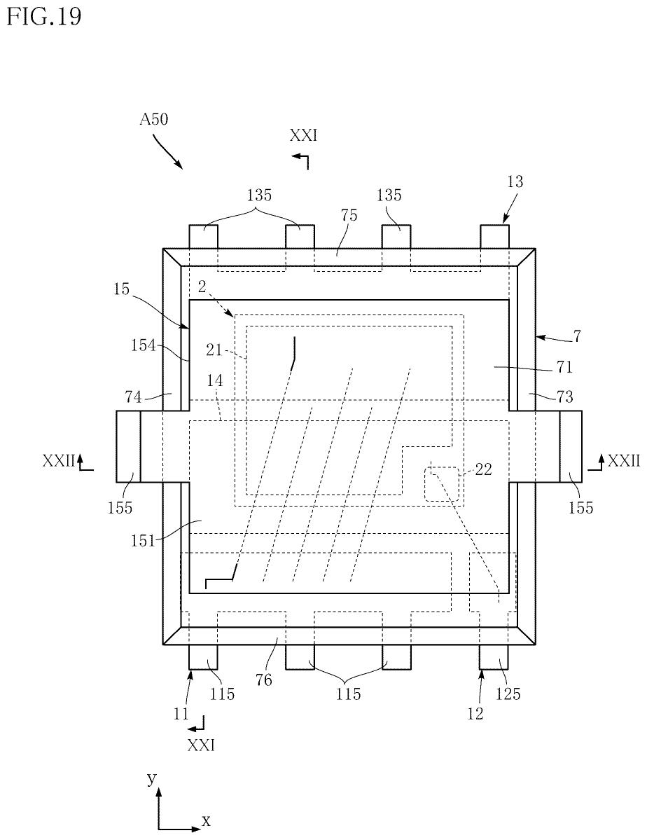

FIGS. 19 to 22 show a semiconductor device A50 and a package structure B50 of a semiconductor device according to a fifth embodiment of the present disclosure. The semiconductor device A50 according to the present embodiment includes a fifth lead 15, and is similar to the semiconductor device A10 in terms of the configurations other than the fifth lead 15.

The fifth lead 15 is made of the same material as the first lead 11, the second lead 12, the third lead 13, and the fourth lead 14. The fifth lead 15 has a main portion 154 and two extending portions 155.

The main portion 154 is located on the first side in the z direction with respect to the semiconductor element 2. The main portion 154 overlaps with the entirety of the semiconductor element 2 as viewed in the z direction. In the illustrated example, the main portion 154 has a rectangular shape. The sealing resin 7 is interposed between the main portion 154 and each of the semiconductor element 2, the wires 65, and the wire 66. The surface of the main portion 154 facing the first side in the z direction is a fifth obverse surface 151.

The two extending portions 155 extend from the main portion 154 to the respective sides in the x direction. Each of the extending portions 155 has a first portion 1551, a second portion 1552, and a third portion 1553. The first portion 1551 is a straight portion extending from the main portion 154 in the x direction. The second portion 1552 is located outside the first portion 1551 in the x direction and on the second side in the z direction. The second portion 1552 has a fifth mounting surface 152. The fifth mounting surface 152 is flush with the first mounting surface 112, the second mounting surface 122, the third mounting surface 132, and the fourth mounting surface 142. The third portion 1553 connects the first portion 1551 and the second portion 1552, and has a shape along the z direction, for example.

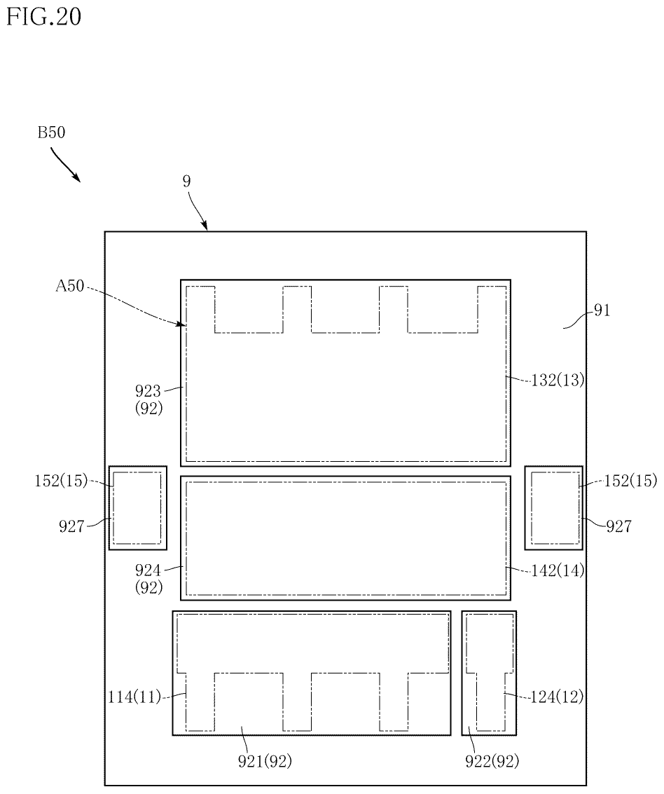

As shown in FIG. 20, the wiring portion 92 of the substrate 9 according to the present embodiment has two seventh regions 927. The two seventh regions 927 are spaced apart from each other and located on the respective sides of the fourth region 924 in the x direction. Each of the seventh regions 927 is electrically connected to a ground line (not illustrated), for example. The fifth mounting surface 152 of each of the two extending portions 155 of the fifth lead 15 is electrically bonded to one of the two seventh regions 927 via a conductive bonding member 87 such as solder.

The present embodiment can also promote heat dissipation and suppress noise. Further, according to the present embodiment, the electromagnetic noise emitted from the semiconductor element 2 to the first side in the z direction can be blocked by the fifth lead 15. This makes it possible to further suppress noise. Since the fifth lead 15 is grounded via the seventh regions 927, noise can be blocked more efficiently.

### Sixth Embodiment

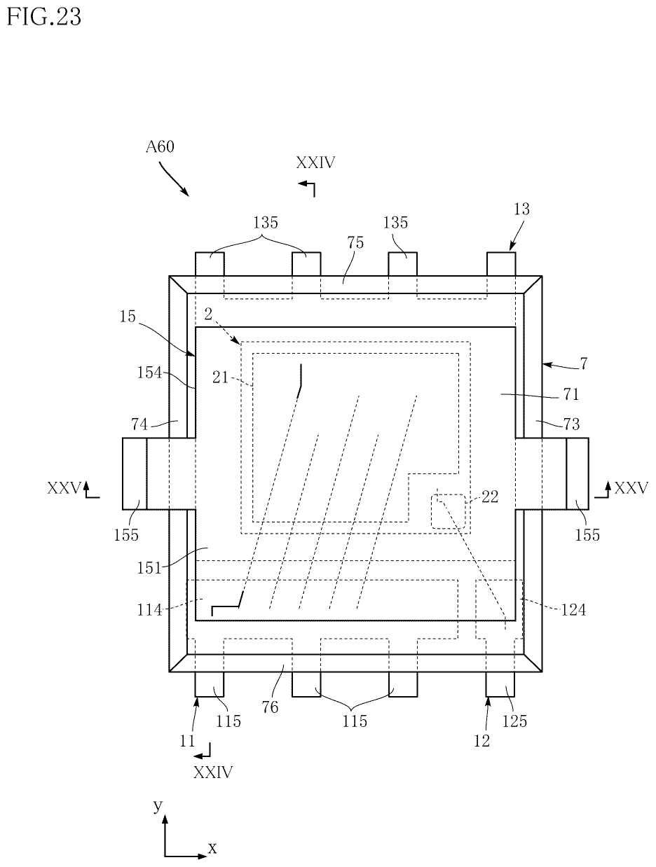

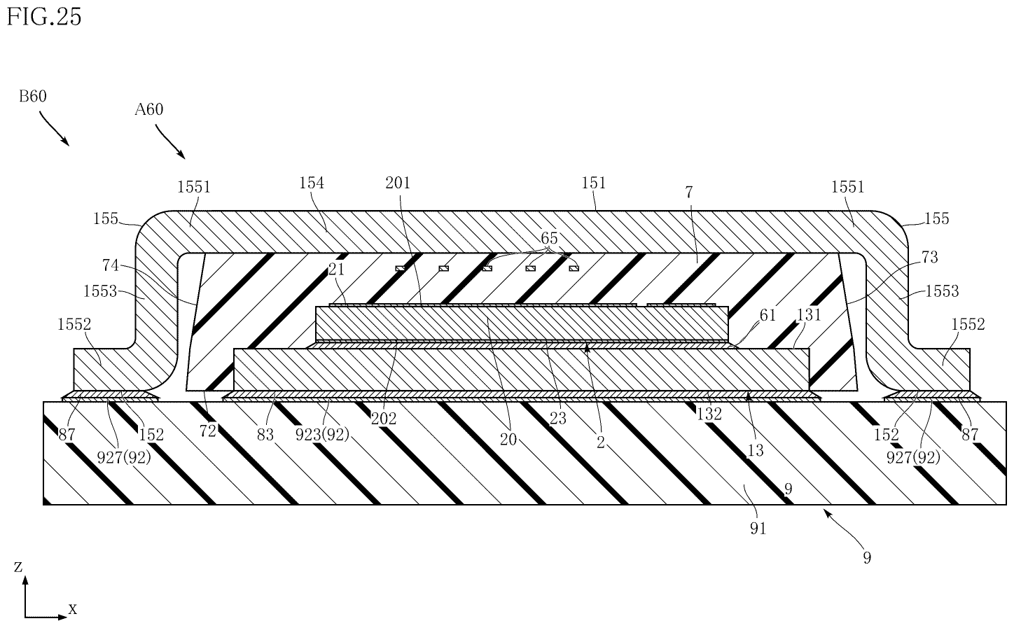

FIGS. 23 to 25 each show a semiconductor device and a package structure of the semiconductor device according to a sixth embodiment of the present disclosure. For convenience of understanding, FIG. 25 additionally shows the substrate 9.

A semiconductor device A60 according to the present embodiment is configured to include the fifth lead 15 described above. The other configurations of the semiconductor device A60 is similar to those of the semiconductor device A40 described above. In other words, the semiconductor device A60 does not include a configuration that intentionally forms a path with a higher impedance.

The substrate 9 of the present embodiment has the same configuration as the substrate 9 of the package structure B50 of a semiconductor device described above. In other words, the fifth lead 15 of the semiconductor device A60 is grounded to the ground line (not illustrated) via the seventh regions 927 of the substrate 9.

The present embodiment can suppress the potential noise emitted from the semiconductor element 2 to the first side in the z direction.

The semiconductor device and the package structure of the semiconductor device according to the present disclosure are not limited to those in the above embodiments. Various design changes can be made to the specific configurations of the elements of the semiconductor device and the package structure of the semiconductor device according to the present disclosure. The present disclosure includes the embodiments described in the following clauses.

### Clause 1.

A semiconductor device comprising:
a semiconductor element including a first electrode and a second electrode located on a first side in a thickness direction and a third electrode located on a second side in the thickness direction, energization of the first electrode and the third electrode being controlled by voltage application to the second electrode;
a first lead electrically connected to the first electrode;
a second lead electrically connected to the second electrode;
a third lead electrically connected to the third electrode;
a fourth lead; and
a sealing resin covering at least the semiconductor element,
wherein the third lead is exposed from the sealing resin to the second side in the thickness direction,
the fourth lead is bonded to the semiconductor element and exposed from the sealing resin to the second side in the thickness direction, and
the semiconductor element includes a switching function unit, an impedance of a path from the switching function unit to the fourth lead being larger than an impedance of a path from the switching function unit to the third lead.

### Clause 2.

The semiconductor device according to clause 1, further comprising:
a first bonding portion bonding the third electrode and the third lead; and
a second bonding portion bonding the third electrode and the fourth lead,
wherein an impedance of the second bonding portion is larger than an impedance of the first bonding portion.

### Clause 3.

The semiconductor device according to clause 2, wherein the first bonding portion contains metal.

### Clause 4.

The semiconductor device according to clause 3, wherein the second bonding portion contains resin.

### Clause 5.

The semiconductor device according to clause 3, wherein the second bonding portion contains ceramic.

### Clause 6.

The semiconductor device according to clause 1, wherein the semiconductor element includes an element body with the first electrode and the second electrode arranged on the first side in the thickness direction and the third electrode arranged on the second side in the thickness direction, and a fourth electrode arranged on the element body on the second side in the thickness direction,
the fourth electrode is bonded to the fourth lead, and
an impedance of a path from the switching function unit to the fourth electrode is larger than an impedance from the switching function unit to the third electrode.

### Clause 7.

The semiconductor device according to clause 6, wherein the semiconductor element includes an insulating layer provided between the element body and the fourth electrode.

### Clause 8.

The semiconductor device according to clause 6, wherein the element body of the semiconductor element includes two diodes having opposite polarities, the diodes being electrically interposed between the third electrode and the fourth electrode and connected in series.

### Clause 9.

The semiconductor device according to any of clauses 1 to 8, wherein the third lead includes a third mounting surface facing the second side in the thickness direction and exposed from the sealing resin,
the first lead includes a first mounting surface facing the second side in the thickness direction and exposed from the sealing resin,
the second lead includes a second mounting surface facing the second side in the thickness direction and exposed from the sealing resin,
the fourth lead includes a fourth mounting surface facing the second side in the thickness direction and exposed from the sealing resin, and
the third mounting surface, the first mounting surface, the second mounting surface, and the fourth mounting surface are flush with each other.

### Clause 10.

The semiconductor device according to clause 9, wherein an area of each of the third mounting surface and the fourth mounting surface is larger than an area of either one of the first mounting surface and the second mounting surface.

### Clause 11.

The semiconductor device according to clause 10, wherein the third mounting surface and the fourth mounting surface are located on a first side in a first direction perpendicular to the thickness direction with respect to the first mounting surface and the second mounting surface.

### Clause 12.

The semiconductor device according to clause 11, wherein the fourth mounting surface is located between the third mounting surface and each of the first mounting surface and the second mounting surface in the first direction.

### Clause 13.

The semiconductor device according to any of clauses 1 to 12, further comprising a fifth lead including a main portion located on the first side in the thickness direction with respect to the semiconductor element.

### Clause 14.

The semiconductor device according to clause 13, wherein the main portion overlaps with an entirety of the semiconductor element as viewed in the thickness direction.

### Clause 15.

The semiconductor device according to clause 14, wherein the fifth lead includes an extending portion extending in a direction intersecting the thickness direction, and the extending portion includes a fifth mounting surface facing the second side in the thickness direction.

### Clause 16.

The semiconductor device according to any of clauses 13 to 15, wherein the fifth lead is exposed from the sealing resin to the first side in the thickness direction.

### Clause 17.

A package structure of a semiconductor device, comprising:
a semiconductor device; and
a substrate on which the semiconductor device is mounted,
wherein the semiconductor device includes:
a semiconductor element including a first electrode, a second electrode, and a third electrode, energization of the first electrode and the third electrode being controlled by voltage application to the second electrode;
a first lead electrically connected to the first electrode;
a second lead electrically connected to the second electrode;
a third lead electrically connected to the third electrode; and
a sealing resin covering at least the semiconductor element,
wherein the substrate includes an insulating portion and a wiring portion,
the wiring portion includes a first region electrically bonded to the first lead, a second region electrically bonded to the second lead, a third region electrically bonded to the third lead, a fourth region adjacent to the third region and electrically bonded to the third lead, a fifth region connected to a ground, a sixth region electrically interposed between the fourth region and the fifth region, and a main current terminal electrically connected to the third region, and
an impedance of a path from the third lead to the fifth region via the fourth region and the sixth region is larger than an impedance of a path from the third lead to the main current terminal.

### Clause 18.

The package structure of a semiconductor device according to clause 17, wherein the fourth region and the fifth region are spaced apart from each other in a thickness direction of the substrate, and
the sixth region includes a plurality of vias connecting the fourth region and the fifth region in the thickness direction.

### REFERENCE NUMERALS

A10, A11, A12, A20: Semiconductor device
A30, A40, A50, A60: Semiconductor device
B10, B40, B50: Package structure
Z1, Z2, Z3, Z4: Impedance
2: Semiconductor element 7: Sealing resin
9: Substrate 11: First lead
12: Second lead 13: Third lead
14: Fourth lead 15: Fifth lead
20: Element body 21: First electrode
22: Second electrode 23: Third electrode
24: Fourth electrode 28: Insulating element portion
61: First bonding portion 62: Second bonding portion
63: Third bonding portion 65, 66: Wire
67: Conductive member 71: Sealing resin obverse surface
72: Sealing resin reverse surface
73, 74, 75, 76: Sealing resin side surface
81, 82, 83, 84, 87: Conductive bonding member
91: Insulating portion
92: Wiring portion 111: First obverse surface
112: First mounting surface 114: First bonding portion
115: First extending portion 121: Second obverse surface
122: Second mounting surface 124: Second bonding portion
125: Second extending portion 131: Third obverse surface
132: Third mounting surface 134: Third bonding portion
135: Third extending portion 141: Fourth obverse surface
142: Fourth mounting surface 151: Fifth obverse surface
152: Fifth mounting surface 154: Main portion
155: Extending portion 200: Switching function unit
201: Element obverse surface 202: Element reverse surface
209: Element insulating layer 281, 282: Diode
621: Insulating layer 622, 623: Metal layer
624, 625: Conductive bonding member 921: First region
922: Second region 923: Third region
924: Fourth region 925: Fifth region
926: Sixth region 927: Seventh region
931: First terminal 932: Second terminal
933: Third terminal 934: Ground terminal
1551: First portion 1552: Second portion
1553: Third portion

1. A semiconductor device comprising:
a semiconductor element including a first electrode and a second electrode located on a first side in a thickness direction and a third electrode located on a second side in the thickness direction, energization of the first electrode and the third electrode being controlled by voltage application to the second electrode;
a first lead electrically connected to the first electrode;
a second lead electrically connected to the second electrode;
a third lead electrically connected to the third electrode;
a fourth lead; and
a sealing resin covering at least the semiconductor element,
wherein the third lead is exposed from the sealing resin to the second side in the thickness direction,
the fourth lead is bonded to the semiconductor element and exposed from the sealing resin to the second side in the thickness direction, and
the semiconductor element includes a switching function unit, an impedance of a path from the switching function unit to the fourth lead being larger than an impedance of a path from the switching function unit to the third lead.

2. The semiconductor device according to claim 1, further comprising:
a first bonding portion bonding the third electrode and the third lead; and
a second bonding portion bonding the third electrode and the fourth lead,
wherein an impedance of the second bonding portion is larger than an impedance of the first bonding portion.

3. The semiconductor device according to claim 2, wherein the first bonding portion contains metal.

4. The semiconductor device according to claim 3, wherein the second bonding portion contains resin.

5. The semiconductor device according to claim 3, wherein the second bonding portion contains ceramic.

6. The semiconductor device according to claim 1, wherein the semiconductor element includes an element body with the first electrode and the second electrode arranged on the first side in the thickness direction and the third electrode arranged on the second side in the thickness direction, and a fourth electrode arranged on the element body on the second side in the thickness direction,
the fourth electrode is bonded to the fourth lead, and
an impedance of a path from the switching function unit to the fourth electrode is larger than an impedance from the switching function unit to the third electrode.

7. The semiconductor device according to claim 6, wherein the semiconductor element includes an insulating layer provided between the element body and the fourth electrode.

8. The semiconductor device according to claim 6, wherein the element body of the semiconductor element includes two diodes having opposite polarities, the diodes being electrically interposed between the third electrode and the fourth electrode and connected in series.

9. The semiconductor device according to claim 1, wherein the third lead includes a third mounting surface facing the second side in the thickness direction and exposed from the sealing resin,
the first lead includes a first mounting surface facing the second side in the thickness direction and exposed from the sealing resin,
the second lead includes a second mounting surface facing the second side in the thickness direction and exposed from the sealing resin,
the fourth lead includes a fourth mounting surface facing the second side in the thickness direction and exposed from the sealing resin, and
the third mounting surface, the first mounting surface, the second mounting surface, and the fourth mounting surface are flush with each other.

10. The semiconductor device according to claim 9, wherein an area of each of the third mounting surface and the fourth mounting surface is larger than an area of either one of the first mounting surface and the second mounting surface.

11. The semiconductor device according to claim 10, wherein the third mounting surface and the fourth mounting surface are located on a first side in a first direction perpendicular to the thickness direction with respect to the first mounting surface and the second mounting surface.

12. The semiconductor device according to claim 11, wherein the fourth mounting surface is located between the third mounting surface and each of the first mounting surface and the second mounting surface in the first direction.

13. The semiconductor device according to claim 1, further comprising a fifth lead including a main portion located on the first side in the thickness direction with respect to the semiconductor element.

14. The semiconductor device according to claim 13, wherein the main portion overlaps with an entirety of the semiconductor element as viewed in the thickness direction.

15. The semiconductor device according to claim 14, wherein the fifth lead includes an extending portion extending in a direction intersecting the thickness direction, and
the extending portion includes a fifth mounting surface facing the second side in the thickness direction.

16. The semiconductor device according to claim 13, wherein the fifth lead is exposed from the sealing resin to the first side in the thickness direction.

17. A package structure of a semiconductor device, comprising:
a semiconductor device; and
a substrate on which the semiconductor device is mounted,
wherein the semiconductor device includes:
a semiconductor element including a first electrode, a second electrode, and a third electrode, energization of the first electrode and the third electrode being controlled by voltage application to the second electrode;
a first lead electrically connected to the first electrode;
a second lead electrically connected to the second electrode;
a third lead electrically connected to the third electrode; and
a sealing resin covering at least the semiconductor element,
wherein the substrate includes an insulating portion and a wiring portion,
the wiring portion includes a first region electrically bonded to the first lead, a second region electrically bonded to the second lead, a third region electrically bonded to the third lead, a fourth region adjacent to the third region and electrically bonded to the third lead, a fifth region connected to a ground, a sixth region electrically interposed between the fourth region and the fifth region, and a main current terminal electrically connected to the third region, and
an impedance of a path from the third lead to the fifth region via the fourth region and the sixth region is larger than an impedance of a path from the third lead to the main current terminal.

18. The package structure of a semiconductor device according to claim 17, wherein the fourth region and the fifth region are spaced apart from each other in a thickness direction of the substrate, and
the sixth region includes a plurality of vias connecting the fourth region and the fifth region in the thickness direction.
